(19) United States
(12) Patent Application Publication
(10) Pub. No.: US 2009/0241335 A1
(43) Pub. Date: Oct. 1, 2009

(54) WIRING WORK SUPPORT DEVICE

(75) Inventors: Shunsuke SONE, Kawasaki (JP); Hirokazu YAMANISHI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/399,566

(22) Filed: Mar. 6, 2009

(30) Foreign Application Priority Data
Mar. 25, 2008 (JP) 2008-078531

(51) Int. Cl. H05K 13/00

(52) U.S. Cl. 29/854

(57) ABSTRACT

A wiring work support device includes a database storing information of an object lead or an object pad, an image input part taking an image of a printed-circuit board, a position specification part specifying a position of the object lead or the object pad on the printed-circuit board on the basis of information stored in the database and image data from the image input part and a position teaching part. The position teaching part superposes, marks and displays the position on the printed-circuit board, specified by the position specification part, on an actual printed-circuit board or an image in which the printed-circuit board is displayed.

### CROSS-REFERENCE TO RELATED APPLICATION

This application is based upon and claims the benefit of priority of prior Japanese Patent Application No. 2008-78531, filed on Mar. 25, 2008, the entire contents of which are incorporated herein by reference.

### FIELD

The embodiment discussed herein is related to a wiring work support device which supports a manual wiring work for a printed-circuit board (PCB) with parts mounted thereon.

### BACKGROUND

When a printed-circuit board with parts mounted thereon may be, for example, changed in design or repaired, a wiring pattern is cut, or a wiring work is performed. The wiring work is a work for soldering both ends of a jumper line to a lead or pad of a semiconductor chip. The pad is a conductive land, which is provided in a printed-circuit board for the purpose of connecting a lead of a surface mounting part to the printed-circuit board by means of solder.

The wiring work is performed for adjustment, whereby it is applied to a small lot and varies. Particularly, the wiring work for repair is different from one printed-circuit board to another, and therefore, the wiring work is manually performed by an operator with a soldering iron. Considering that the wiring work is a return work and a manual work, the reduction of the time needed for the wiring work contributes significantly to the reduction of the whole tact time and the reduction of labor costs.

A related work support device instructs, on a display, an operator to perform a work on the basis of input information such as a work drawing and a mounting drawing. Usually, the device provides an effect of reduction of a fixed period of time in terms of eliminating setup such as arrangement for a work drawing from a paper-based work instruction.

FIG. 1 is a view illustrating a flow of the prior art wiring work. In FIG. 1, when the related work support device is used, the time needed for recognizing object chips A and B from the work instruction (step 102) is reduced from 30 seconds to 10 seconds in comparison with the case where the device are not used. However, as viewed from the whole work, the time occupied by the recognition of the object chips is only about 20% of the total.

In FIG. 1, all works other than the work of actually attaching a jumper line to a lead (steps 108 and 114) are setup works. The setup works occupying the majority of the wiring work include reading an object chip and an object lead number from a work instruction to specify a position on an actual printed-circuit board. The time needed for the setup works may not be significantly reduced unless the setup work is improved. Recently, the increasing of the density of chips and the reduction of the pitch of a chip lead and a printed-circuit board associated with the increasing of the density of chips has progressed, and therefore, this tendency is more pronounced. In addition, the pitch of the chip lead and the printed-circuit board is reduced to thereby easily cause an error of the attachment position of a jumper line due to an error of counting leads.

An operator obtains the position information of an object chip from a paper work instruction or an instruction on a display to run the position information with the actual printed-circuit board, and, thus, to specify the position of the chip on the printed-circuit board. Thereafter, the operator counts the position of a lead, to which a jumper line may be attached, from the end to specify the position. As mentioned above, recently, the reduction of the pitch of a chip is progressed, and therefore, the count of leads is troublesome. Further, it is impossible to mark on the actual printed-circuit board as a product. Therefore, if the operator temporarily looks aside from the printed-circuit board in order to, for example, prepare tools, he needs to specify the position again, and thus, unnecessary work is easily created.

### SUMMARY

According to an aspect of the embodiment, a wiring work support device which supports a manual wiring work for a printed-circuit board with parts mounted thereon, includes a database capable of storing information of an object lead or an object pad of a part which is an object for the wiring work, an image input part which takes an image of the printed-circuit board, a position specification part which specifies a position of the object lead or the object pad on the printed-circuit board on the basis of information stored in the database and image data from the image input part, and a position teaching part which superposes, marks and displays the position on the printed-circuit board, specified by the position specification part, on an actual printed-circuit board or an image in which the printed-circuit board is displayed.

In keeping with another aspect of an embodiment of this technique, a wiring work supporting method is executed by using a database capable of storing information of an object lead or an object pad of a part which is an object for a wiring work and supports a manual wiring work for a printed-circuit board with parts mounted thereon. The method includes an image input operation of, by an image input part, taking an image of the printed-circuit board, a position specification operation of, by a position specification part, specifying a position of an object lead or an object pad on the printed-circuit board on the basis of information stored in the database and image data from the image input part, and a position teaching operation of, by a position teaching part, superposing, marking and displaying the position on the printed-circuit board, specified in the position specification operation, on an actual printed-circuit board or an image in which the printed-circuit board is displayed.

The object and advantages of the embodiment will be realized and attained by means of the elements and combinations particularly pointed out in the claims.

It is to be understood that both the foregoing general description and the following detailed are exemplary and explanatory and are not restrictive of the embodiment, as claimed.

### BRIEF DESCRIPTION OF DRAWINGS

Embodiments are illustrated by way of example and not limited by the following figures.

FIG. 1 is a view illustrating a flow of a wiring work.

FIG. 2 is a functional block diagram illustrating a basic constitution of a wiring work support device.

FIG. 3 is a view illustrating an example of a specific constitution of the wiring work support device.

FIG. 4 is a block diagram illustrating an example of an internal constitution of a personal computer.

FIG. 5 is a view illustrating an arrangement of a camera and a display.

FIG. 6 is a view exemplifying a display screen of the display.

FIG. 7 is a flow chart illustrating a procedure of a wiring position teaching processing performed by the personal computer.

FIG. 8 is a flow chart illustrating a procedure of a tool information indicating processing performed by the personal computer.

FIG. 9 is a view illustrating iron tip slopes of a soldering iron.

FIG. 10 is a view illustrating a flow of a wiring work.

FIG. 11 is a view for explaining an arrangement of a projector and display for another embodiment.

### DESCRIPTION OF EMBODIMENTS

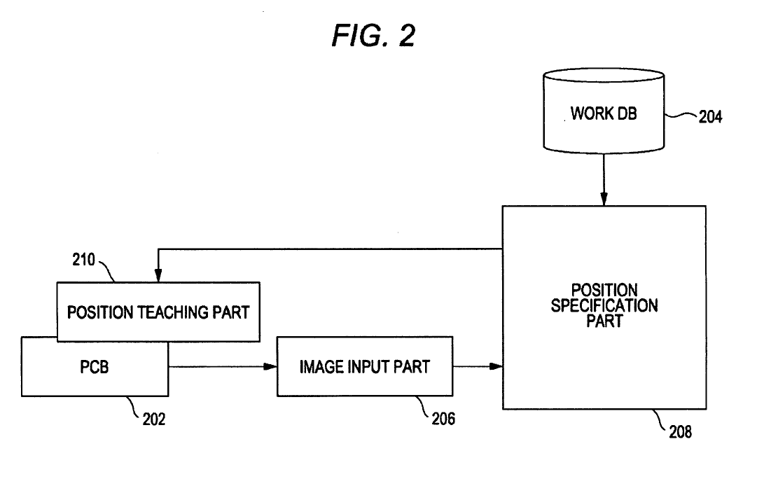

Preferred embodiments of the present invention will be explained with reference to accompanying drawings. FIG. 2 is a functional block diagram illustrating a basic constitution of a wiring work support device according to one embodiment of the invention. The wiring work support device supports a manual wiring work for a printed-circuit board (PCB) 202 with parts mounted thereon and includes a work database (DB) 204, an image input part 206, a position specification part 208, and a position teaching part 210.

The database 204 stores information of an object to be subjected to the wiring work, that is, an object lead or an object pad of an object part which is a connection source and a connection destination. When the pad is an object for the wiring work, the number of the corresponding lead connected with the pad is registered as an object lead in the database 204, and, at the same time, the X direction distance and the Y direction distance of the pad based on the lead are registered in the database 204. Further, a master image for matching showing an outline of an object chip is registered in the database 204. Still further, an iron tip image for matching showing an outline of an iron tip of a soldering iron as a tool for the wiring work is registered in the database 204.

The image input part 206 takes an image of the printed-circuit board 202 to output image data as streaming data. The position specification part 208 specifies the position of the object lead or the object pad on the printed-circuit board by means of an image processing on the basis of the information stored in the work database 204 and the image data from the image input part 206. The position teaching part 210 superposes, marks and displays the position of the object lead or the object pad on the printed-circuit board, specified by the position specification part 208, on an actual printed-circuit board or an image in which the printed-circuit board is displayed. Hereinafter, the constitution which can realize the functional block illustrated in FIG. 2 is described.

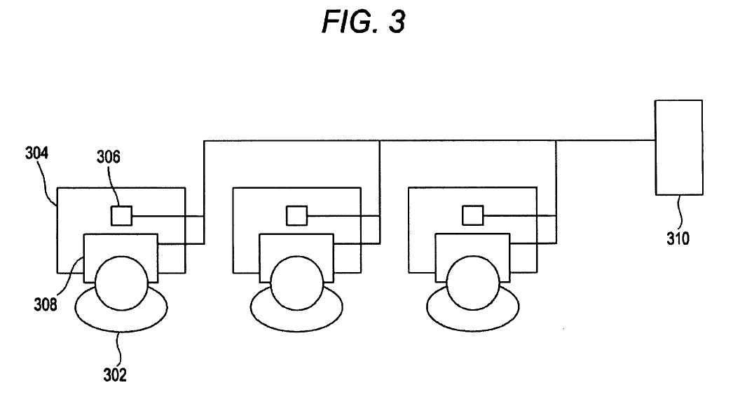

FIG. 3 is a view illustrating an example of a specific constitution of the wiring work support device according to this embodiment. The wiring work support device is a computer system for supporting a wiring work on a work table 304 performed by three operators 302, and has a camera 306 and a display 308 provided for each operator and a personal computer (PC) 310 as an input and output device for controlling the camera 306 and the display 308. Here, the camera 306 operates as the image input part 206 of FIG. 2. The computer 310 operates as the work database 204 and the position specification part 208 of FIG. 2. The display 308 operates as the position teaching part 210 of FIG. 2.

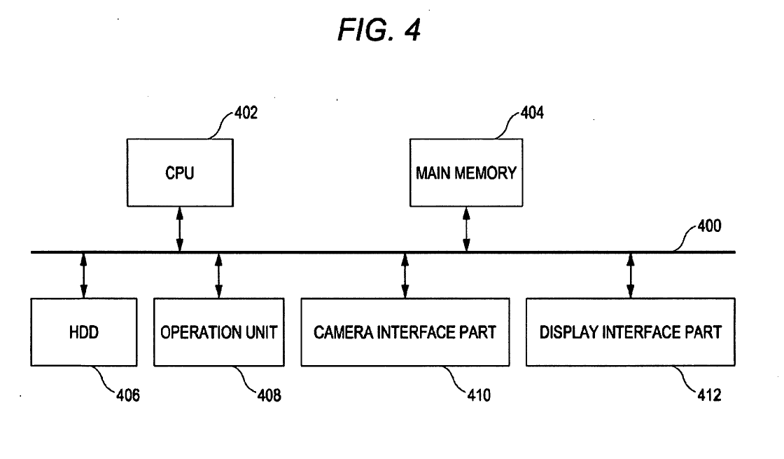

FIG. 4 is a block diagram illustrating an example of the internal constitution of the personal computer 310. As illustrated in FIG. 4, the personal computer 310 has a central processing unit (CPU) 402, a main storage device 404, a hard disk drive (HDD) 406 as an auxiliary (external) storage device, an operation unit 408 constituted of a keyboard and a mouse, a camera interface part 410, a display interface part 412, and so on. The CPU 402 is connected to other components through a bus 400 and executes a program loaded in the main storage device 404 to thereby realize the processing to be hereinafter described.

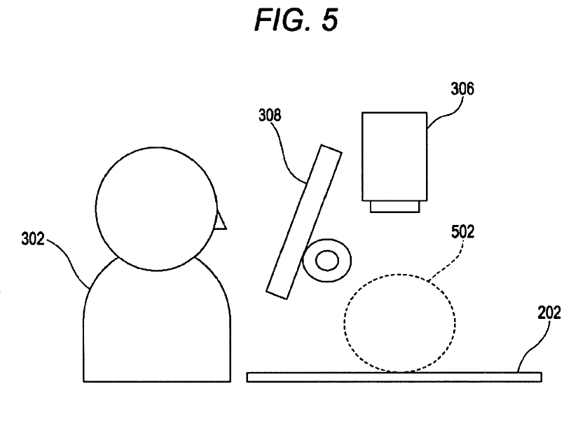

FIG. 5 is a view illustrating the arrangement of the camera 306 and the display 308. As illustrated in FIG. 5, the camera 306 is disposed above the printed-circuit board 202 and captures the printed-circuit board 202 in the view. The display 308 is disposed between the operator 302 and the printed-circuit board 202. Thus, as illustrated in FIG. 5, a work space 502 is secured, and the operator 302 can work while watching the display 308.

As described above, the actual attachment work of a jumper line is often performed through a stationary magnifying glass with the reduction of the pitch of a chip lead in recent years. The function of the magnifying glass is covered by the camera 306 and the display 308, and these equipments are disposed as illustrated in FIG. 5, whereby the operator 302 can perform the wiring work while visually confirming an enlarged image, and, at the same time, the position of the object lead or the object pad is superposed, marked and displayed on an image from the camera 306, whereby the operator 302 can proceed with the wiring work on the basis of only an image on the display 308.

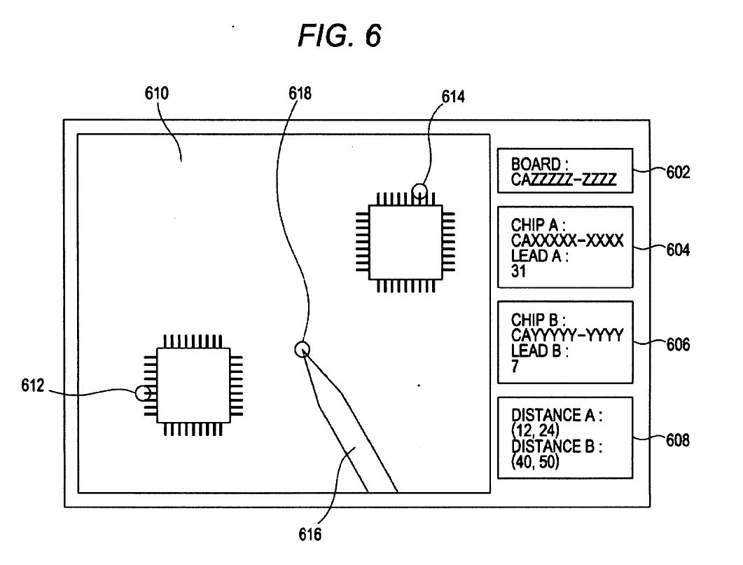

FIG. 6 is a view exemplifying a display screen of the display 308. As illustrated in FIG. 6, the display 308 includes a printed-circuit board (PCB) information display area 602, a connection source information display area 604, a connection destination information display area 606, a tool information display area 608, and a circuit image display area 610.

The information for specifying a printed-circuit board, which is an object for the wiring work, is displayed in the printed-circuit board (PCB) information display area 602. The information for specifying an object chip to which one end of a jumper line may be soldered (for example, combination of the model numbers of chips and the tracking numbers in the PCB) and the information for specifying an object lead or an object pad (for example, a lead number) are respectively displayed in the connection source information display area 604 and the connection destination information display area 606.

An image of all or part of an object PCB monitored by the camera 306 is displayed in the circuit image display area 610. In this image, actual positions 612 and 614 of an object lead or an object pad of an object chip displayed in the connection source information display area 604 and the connection destination information display area 606 are marked and displayed. A soldering iron 616 as a tool for the wiring work is captured by the camera 306 to be displayed in the circuit image display area 610.

The distance from a top end 618 of the soldering iron 616 to one position 612 of an object lead or an object pad (represented by the combination of the X-axis direction distance and the Y-axis direction distance) and the distance from the top end 618 of the soldering iron 616 to the other position 614 of the object lead or the object pad are displayed in the tool information display area 608. Hereinafter, a wiring position teaching processing and a tool information indicating processing illustrated in FIG. 6 are described.

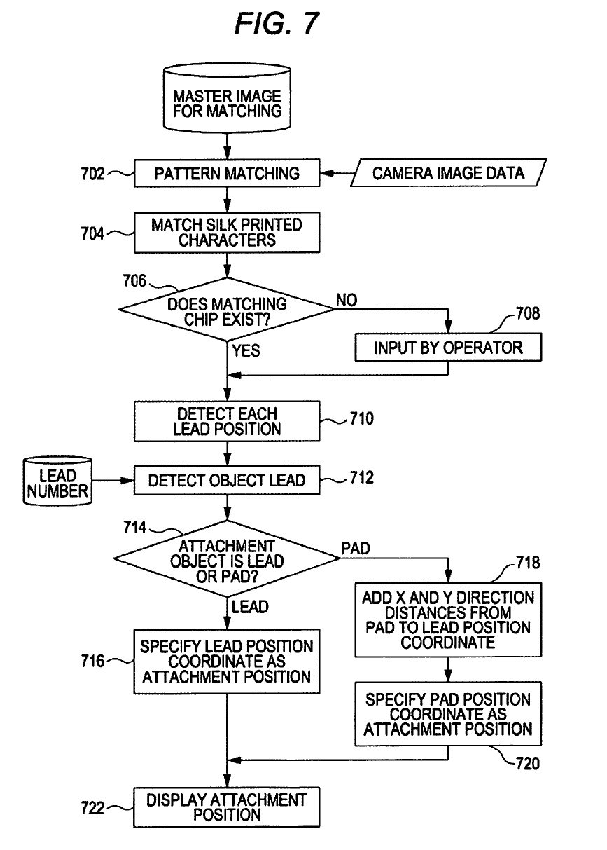

FIG. 7 is a flow chart illustrating a procedure of the wiring position teaching processing performed by the personal computer 310. The personal computer 310 first performs pattern matching based on a master image for matching of an object chip from the database 204 and image data from the camera 306 to thereby detect the position on the PCB on which a chip matching the model number of the object chip is mounted (step 702). A plurality of positions may be detected.

The personal computer 310 then matches silk printed characters on the detected chip to thereby detect a chip matching the tracking number in the PCB of the object chip (step 704). The object chip is specified in steps 702 and 704, and the attachment direction is obtained.

When the chip matching the object chip may not be detected at that time, the personal computer 310 prompts the operator to visually detect the object chip and then to input the position of the object chip (steps 706 and 708).

The personal computer 310 then detects each lead position in the chips detected as the object chip by means of an edge extraction processing (step 710). In the edge extraction processing, differential operation is applied to a gradation of a pixel of image data, whereby an edge image is obtained.

The personal computer 310 then counts the detected lead position to thereby detect, as an object lead position, the lead position matching lead number information from the database 204 (step 712).

When the object for the attachment of a wiring is a lead, the personal computer 310 specifies the detected object lead position as the attachment position of a jumper line (steps 714 and 716).

Meanwhile, when the object for the attachment of the wiring is a pad, the personal computer 310 adds the X and Y direction distances of the object pad based on the object lead position to the coordinate of the object lead position (steps 714 and 718). The personal computer 310 then specifies as the attachment position of the jumper line the coordinate of an object pad position obtained by the addition (step 720). When the object for the attachment of the wiring is a pad, the object pad is specified after the detection of the object lead, because if solder is put on the pad itself, it is assumed that it is difficult to stably detect the pad by an image processing.

Finally, the personal computer 310 marks and displays the specified jumper line attachment position in the circuit image display area 610 in the display 308 (step 722). The position specified by the above processings is always superposed and displayed on a streaming image, and therefore, the operator may confirm the position in real time.

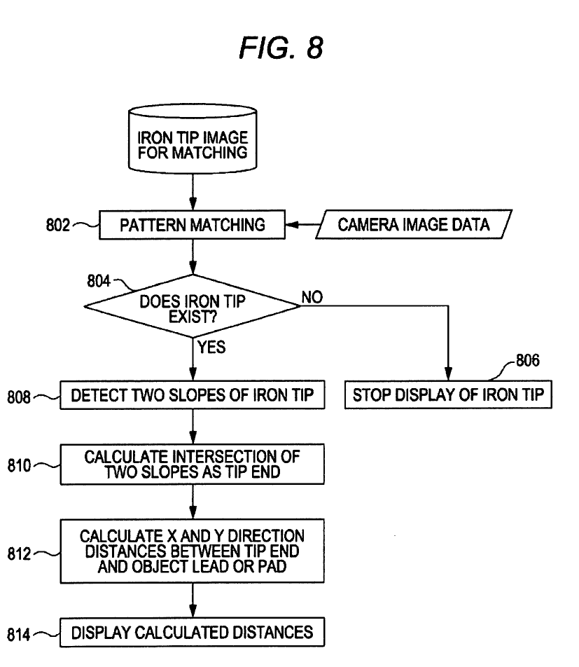

FIG. 8 is a flow chart illustrating a procedure of the tool information indicating processing performed by the personal computer 310. The personal computer 310 first performs pattern matching based on an iron tip image for matching from the database 204 and the image data from the camera 306 to thereby attempt to detect the iron tip of the soldering iron 616 (step 802).

The personal computer 310 then determines whether the iron tip of the soldering iron 616 exists in the field of view of the camera 306 (step 804). When the iron tip does not exist therein, the personal computer 310 stops the display of the tool information display area 608 (FIG. 6) (step 806).

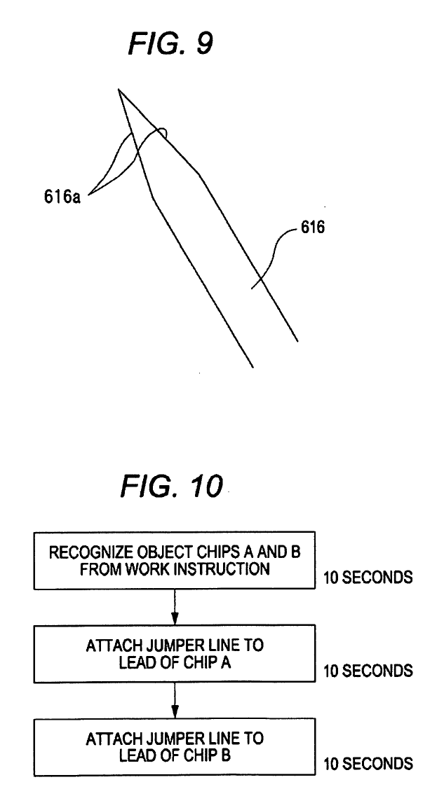

Meanwhile, when the iron tips of the soldering iron 616 exists in the field of view of the camera 306, the personal computer 310 detects two slopes 616a of the iron tip illustrated in FIG. 9 by the edge extraction processing (step 808). The personal computer 310 then calculates the intersection of the two slopes (edge) as the position of the top end 618 of the soldering iron 616 (step 810). Solder or the like is adhered to the top end of the iron tip, whereby the position of the top end of the soldering iron may not be stably detected, and therefore, in this embodiment, two straight lines of the slopes 616a of the iron tip illustrated in FIG. 9 are specified by the edge extraction processing, and the intersection of the two straight lines is obtained by calculation, whereby the intersection is assumed to be the top end 618 of the soldering iron 616.

The personal computer 310 then calculates the X-axis and Y-axis direction distances from the top end 618 of the soldering iron 616 to an object lead or an object pad (step 812). Finally, the personal computer 310 displays the distance between the iron tip and the object lead or the object pad in the tool information display area 608 (FIG. 6) (step 814). Such distance information prompts the operator to prevent any erroneous attachment.

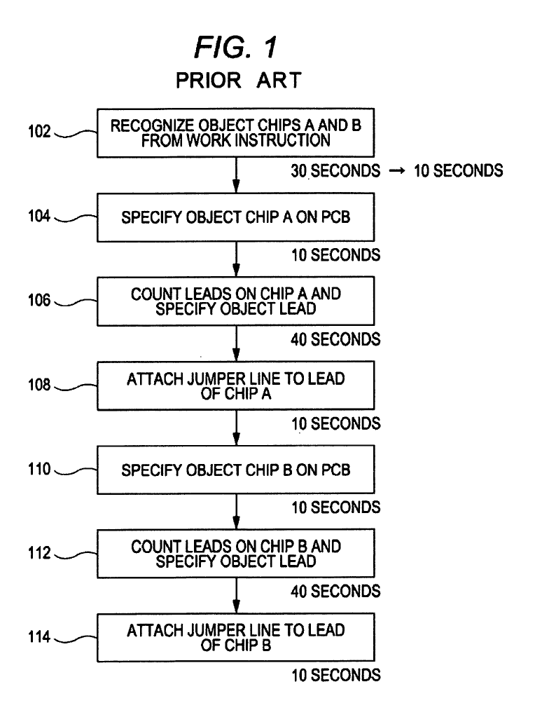

FIG. 10 is a view illustrating a flow of a wiring work using this embodiment. As seen in comparison with FIG. 1, the works for setup may be omitted in this embodiment, whereby the number of processes may be substantially reduced. Namely, the time needed for setup such as visually confirmation of the attachment position of a jumper line may be reduced (down 80%), and, at the same time, error such as to attach the jumper line to an unintended lead and the inspection process associated with the wiring work may be reduced.

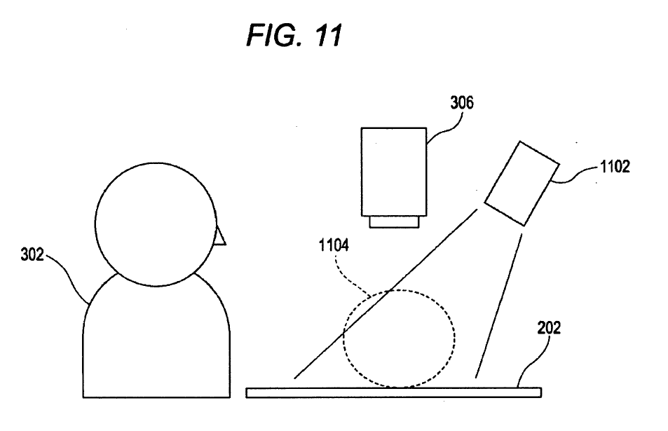

FIG. 11 is a view for explaining another embodiment of the invention. As seen in comparison with FIG. 5, in this embodiment, as in FIG. 5, the camera 306 is disposed above the printed-circuit board 202 and captures the printed-circuit board 202 in the view. However, the display 308 is not provided, and a projector 1102 as a position teaching part is disposed instead of the display 308.

The projector 1102 projects an image in which the attachment position is displayed on the printed-circuit board 202 to thereby teach the attachment position. In this embodiment, an attachment work space 1104 larger than the work space in FIG. 5 may be secured. The distance between the position of an iron tip of a soldering iron and the attachment position is indicated to the operator by using a sound or the like so as not to reduce the workability. Also in this embodiment, the operation and effect similar to those of the above embodiment may be obtained.

According to the disclosed wiring work support device, the time needed for setup such as visually confirmation of the attachment position of a jumper line may be reduced, and, at the same time, error such as to attach the jumper line to an unintended lead and the inspection process associated with the wiring work may be reduced.

All examples and conditional language recited herein are intended for pedagogical purposes to aid the reader in understanding the invention and the concepts contributed by the inventor to furthering the art, and are to be constructed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A wiring work support device which supports a manual wiring work for a printed-circuit board with parts mounted thereon, comprising:
a database capable of storing information of an object lead or an object pad of a part which is an object for the wiring work;
an image input part which takes an image of the printed-circuit board;
a position specification part which specifies a position of the object lead or the object pad on the printed-circuit board on the basis of information stored in the database and image data from the image input part; and
a position teaching part which superposes, marks and displays the position on the printed-circuit board, specified by the position specification part, on an actual printed-circuit board or an image in which the printed-circuit board is displayed.

2. The wiring work support device according to claim 1, wherein the position teaching part superposes, marks and displays the position on the printed-circuit board, specified by the position specification part, on an image on a display displaying the printed-circuit board.

3. The wiring work support device according to claim 1, wherein the position teaching part projects the position on the printed-circuit board, specified by the position specification part, on the actual printed-circuit board by a projector.

4. The wiring work support device according to claim 1, further comprising a tool information indicating part which recognizes a position of a tool for the wiring work on the printed-circuit board based on image data from the image input part to calculate and indicate a distance between the tool for the wiring work and the object lead or the object pad.

5. The wiring work support device according to claim 4, wherein the tool information indicating part recognizes a top end of a soldering iron as the tool for the wiring work.

6. A wiring work supporting method executed by using a database capable of storing information of an object lead or an object pad of a part which is an object for a wiring work and supports a manual wiring work for a printed-circuit board with parts mounted thereon, the method comprising:
an image input operation of, by an image input part, taking an image of the printed-circuit board;
a position specification operation of, by a position specification part, specifying a position of an object lead or an object pad on the printed-circuit board on the basis of information stored in the database and image data from the image input part; and
a position teaching operation of, by a position teaching part, superposing, marking and displaying the position on the printed-circuit board, specified in the position specification operation, on an actual printed-circuit board or an image in which the printed-circuit board is displayed.

7. The wiring work supporting method according to claim 6, wherein in the position teaching operation, the position on the printed-circuit board specified in the position specification operation is superposed, marked and displayed on an image on a display disposed between an operator and the printed-circuit board and displaying the printed-circuit board.

8. The wiring work supporting method according to claim 6, wherein in the position teaching operation, the position on the printed-circuit board specified in the position specification operation is projected on the actual printed-circuit board by a projector.

9. The wiring work supporting method according to claim 6, further comprising a tool information indicating operation of, by a tool information indicating part, recognizing the position of a tool for the wiring work on the printed-circuit board on the basis of image data input in the image input operation to calculate and indicate the distance between the tool for the wiring work and the object lead or the object pad.

10. The wiring work supporting method according to claim 9, wherein in the tool information indicating operation, a top end of a soldering iron is recognized as the tool for the wiring work.

11. A computer readable storage medium storing a wiring work support program that is able to cause a computer system to support a manual wiring work for a printed-circuit board with parts mounted thereon, the wiring work support program causing a computer to execute:
a database capable of storing information of an object lead or an object pad of a part which is an object for the wiring work;
an image input part which takes an image of the printed-circuit board;
a position specification part which specifies a position of the object lead or the object pad on the printed-circuit board on the basis of information stored in the database and image data from the image input part; and
a position teaching part which superposes, marks and displays the position on the printed-circuit board, specified by the position specification part, on an actual printed-circuit board or an image in which the printed-circuit board is displayed.

12. The wiring work support program according to claim 11, wherein the position teaching part superposes, marks and displays the position on the printed-circuit board, specified by the position specification part, on an image on a display displaying the printed-circuit board.

13. The wiring work support program according to claim 11, wherein the position teaching part projects the position on the printed-circuit board, specified by the position specification part, on the actual printed-circuit board by means of a projector.

14. The wiring work support program according to claim 11, wherein the computer system is further operated as a tool information indicating part which recognizes a position of a tool for the wiring work on the printed-circuit board on the basis of image data from the image input part to calculate and indicate the distance between the tool for the wiring work and the object lead or the object pad.

15. The wiring work support program according to claim 14, wherein the tool information indicating part recognizes a top end of a soldering iron as the tool for the wiring work.
